(19) United States
(12) Patent Application Publication
(10) Pub. No.: US 2016/0172457 A1
(43) Pub. Date: Jun. 16, 2016

(54) METHODS OF FABRICATING SILICON NANOWIRES AND DEVICES CONTAINING SILICON NANOWIRES

(71) Applicant: Board of Regents, The University of Texas System, Austin, TX (US)

(72) Inventors: Paul S. Ho, Austin, TX (US); Zhuojie Wu, Fishkill, NY (US)

(21) Appl. No.: 15/040,025

(22) Filed: Feb. 10, 2016

Related U.S. Application Data
(63) Continuation of application No. PCT/US2014/050907, filed on Aug. 13, 2014.
(60) Provisional application No. 61/865,920, filed on Aug. 14, 2013.

(51) Int. Cl. H01L 29/45; H01L 29/06; H01L 21/321; H01L 31/0224; H01M 4/134; H01L 31/18; H01L 35/34; G01N 27/414; H01M 4/38; H01L 21/3213; H01L 35/04

(52) U.S. Cl. CPC H01L 29/45; H01L 21/32134; H01L 21/32139; H01L 29/0669; H01L 21/321; H01L 31/022425; H01L 35/04; H01L 31/18; H01L 35/34; G01N 27/4146; H01M 4/386; H01M 4/134

(57) ABSTRACT

The present disclosure relates to a method of fabricating a silicon nanowire having a width of 100 nm or less, especially 50 nm or less, by depositing a metal film on a silicon-containing layer, treating the metal film using a wet process to produce an interconnected metal network having gaps on the silicon-containing layer, and etching the silicon-containing layer with a metal-assisted etching process to form a silicon nanowire having a width of 100 nm or less, especially 50 nm or less.

The present disclosure also relates to lithium ion batteries, thermoelectric materials, solar cells, chemical and biological sensors, and drug delivery devices containing silicon nanowires

### TECHNICAL FIELD

The current disclosure relates to methods of fabricating silicon nanowires, including ultra-thin and ultra-dense silicon nanowires. The disclosure also relates to methods of disposing such nanowires on layers and to devices containing silicon nanowires.

### BACKGROUND

Nanowires are an important class of nano-structured materials that have interesting physical and chemical properties. Silicon nanowires (SiNWs) have received extensive attention in the past decade due to the use of silicon in the semiconductor industry and also its high availability as the second most abundant element on Earth. Silicon nanowires show promise for use in a variety of applications, including nanoelectronics, opto-electronics, electromechanical devices, energy conversion and storage, biological and chemical sensors, and drug delivery devices.

Despite the interest in silicon nanowires, there is currently no good method to fabricate large quantities of silicon nanowires, particularly those with a width of 100 nm or less. Furthermore, there is currently no cost-effective process.

### SUMMARY

The present disclosure relates to a method of fabricating a silicon nanowire having a width of 100 nm or less by depositing a metal film on a silicon-containing layer, treating the metal film using a wet process to produce an interconnected metal network having gaps on the silicon-containing layer, and etching the silicon-containing layer with a metal-assisted etching process to form a silicon nanowire having a width of 100 nm or less, especially 50 nm or less.

The present disclosure also relates to lithium ion batteries, thermoelectric materials, solar cells, chemical and biological sensors, and drug delivery devices containing silicon nanowires.

### BRIEF DESCRIPTION OF THE DRAWINGS

A more complete understanding of the present embodiments and advantages thereof may be acquired by referring to the following description taken in conjunction with the accompanying drawings, which relate to embodiments of the present disclosure.

FIG. 1A illustrates a silicon-containing layer with a metal film.

FIG. 1B illustrates a silicon-containing layer with a metal network.

FIG. 1C illustrates a silicon-containing layer with silicon nanowires.

FIG. 2 presents a scanning electron microscope (SEM) image of silicon nanowires.

FIG. 3 presents a transmission electron microscope (TEM) image of a silicon nanowires.

FIG. 4 presents an SEM image of ultra-dense silicon nanowires.

FIG. 5 presents an SEM image of collapsed silicon nanowires.

FIG. 6 presents an SEM image of porous silicon nanowires.

FIG. 7 presents a TEM image of porous silicon nanowires.

FIG. 8 presents SEM images of patterned silicon nanowires.

FIG. 9 presents an SEM image of detached silicon nanowires.

FIG. 10 presents an SEM image of bunched silicon nanowires.

FIG. 11 illustrates a lithium ion battery having an anode containing silicon nanowires.

FIG. 12 illustrates a thermoelectric device containing silicon nanowires.

FIG. 13 illustrates a solar cell containing silicon nanowires.

FIG. 14 illustrates a biological sensor containing silicon nanowires.

FIG. 15 provides an SEM image of 20 nm wide silicon nanowires.

FIG. 16 provides an SEM image of 40 nm wide silicon nanowires.

FIG. 17 provides an SEM image of interconnected silicon nanowires.

FIG. 18 provides an SEM image of a silicon wafer after cycling in a lithium ion battery.

FIG. 19 provides an SEM image of silicon nanowires after cycling in a lithium ion battery.

### DETAILED DESCRIPTION

The current disclosure relates to methods of fabricating silicon nanowires, particularly ultra-think and ultra-dense silicon nanowires. In a specific embodiment, it relates to methods of fabricating silicon nanowires with a width of 100 nm or less, particularly 50 nm or less, or even 30 nm or less. The current disclosure further relates to methods of fabricating interconnected silicon nanowires, sometimes called silicon nanofences. The current disclosure additionally relates to methods of disposing such nanowires on layers and to a variety of devices containing silicon nanowires.

When the term “width” is used in the current specification with respect to silicon nanowires, it refers to either the average width of a silicon nanowire or a collection of silicon nanowires, as indicated by context.

When the term “length” is used in the current specification with respect to silicon nanowires, it refers to either the average length of a silicon nanowire or a collection of silicon nanowires, as indicated by context.

### Method of Fabricating Silicon Nanowires

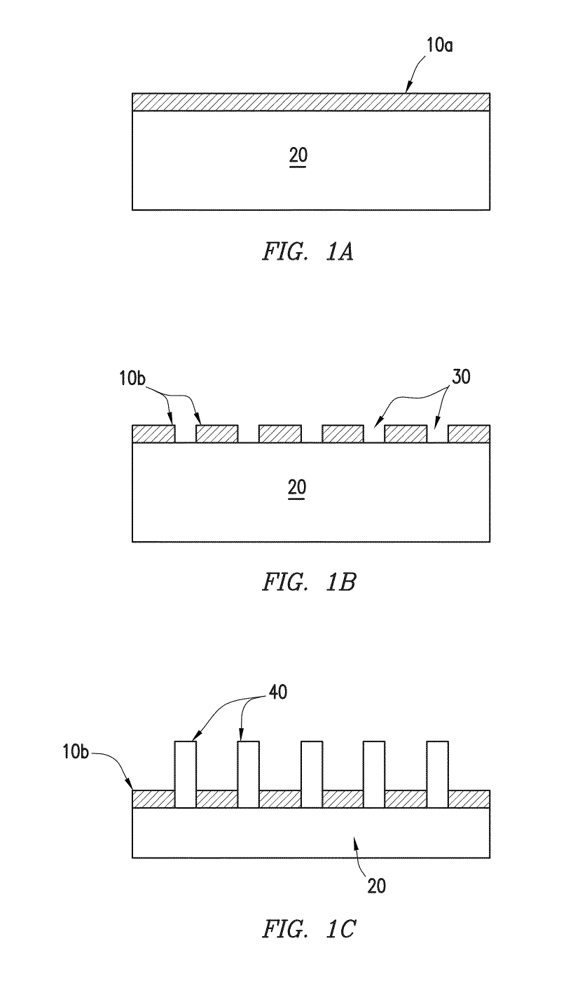

In one embodiment of the disclosure, silicon nanowires may be formed by depositing a metal film 10a on a silicon-containing layer 20 as shown in FIG. 1A. Next, metal film 10 may be treated to form interconnected metal network 10b with gaps 30 as shown in FIG. 1B. Finally, a silicon etching process in which the metal network 10b serves as a catalyst may be used to etch away silicon beneath the metal, producing silicon nanowires 40 where gaps 30 were previously located. The width of silicon nanowires 40 may be controlled by controlling the width of gaps 30. The length of silicon nanowires 40 may be controlled by controlling the etching time and etching conditions. e.g. temperature and etching solution concentration, etc.

In some embodiments, the silicon-containing layer 20 may be polycrystalline silicon or amorphous silicon. It may be, but need not be, a single crystalline silicon wafer. It may be, but need not be, any combinations of polycrystalline silicon, amorphous silicon and single crystalline silicon. In some embodiments, as metal or other conductor layer may be attached to the silicon-containing layer 20 on the opposite side of metal film 10a.

In some embodiments, the metal film 10a may be deposited by physical vapor deposition such as e-beam evaporation, thermal evaporation, sputtering. In some embodiments, the metal film 10a may be deposited by chemical vapor deposition. In a specific embodiment, the metal film may be gold (Au). The thickness of the metal film 10a, along with the wet process treatment time as described below both influence the width of resulting silicon nanowires 40. In a specific embodiment, the metal film may be between 0.1 nm and 200 nm, between 0.5 nm and 100 nm, or between 1 nm and 40 nm. The overall processing temperature during metal film deposition depends on the deposition approach. It can be several hundred degrees Celsius or higher. It may also be 150° C. or less, or even 100° C. or less. For example, it may be performed at room temperature by using e-beam evaporation.

In some embodiments, the metal film 10a may be treated by a wet process to form interconnected metal network 10b. For example, it may be treated with a solution containing hydrogen peroxide (H₂O₂) and sulfuric acid (H₂SO₄), such as piranha solution. Many different mixture ratios can be used. For example, the Piranha solution may be a mixture of 96 wt % sulfuric acid and 30 wt % hydrogen peroxide with a volume ratio of 1:2. In general, the weight percent for H₂SO₄ in the solution may vary from 96 to 2 or less. The weight percent for H₂O₂ in the solution may vary from 30 to 2 or less.

Treatment with the Piranha solution may last for the length of time necessary to obtain gaps 30 corresponding to the desired with of the silicon nanowires 40. In the case of interconnected silicon nanowires or smaller-width silicon nanowires, the length of time will be less. In the case of larger-width silicon nanowires, the length of time will be greater. In some embodiments, the length of time with Piranha solution or another wet process may be between 1 second and 60 minutes. In a more specific embodiment, it will be between 1 minute and 20 minutes. The wet process may be performed at a temperatures of 150° C. or less. For example, it may be performed at room temperature.

In some embodiments, the hydrogen peroxide in piranha solution may be replaced by other oxidizers such as pure oxygen bubble, ozone, chlorine, iodine, ammonium perchlorate, ammonium permanganate, barium peroxide, bromine, calcium chlorate, calcium hypochlorite, chlorine trifluoride, chromic acid, chromium trioxide (chromic anhydride), peroxides such as hydrogen peroxide, magnesium peroxide, dibenzoyl peroxide and sodium peroxide, dinitrogen trioxide, fluorine, perchloric acid, potassium bromate, potassium chlorate, potassium peroxide, propyl nitrate, sodium chlorate, sodium chlorite, sodium perchlorate, and combinations thereof. These materials may be substituted generally as described in US 2009/0256134, incorporated by reference in material part herein.

In other embodiments, the sulfuric acid in piranha solution may be replaced by one or more other acids, such as nitric acid, hydrochloric acid, hydrobromic acid, sulfurous acid, phosphoric acid, phosphorous acid, boric acid, silicic acid, and combinations thereof.

One alternative to piranha solution is a 3:1 mixture of ammonium hydroxide (NH₄OH) with hydrogen peroxide, also known as base piranha. This solution may be heated to 60° C. to start the reaction.

In some embodiments, the silicon etching process may be any metal-assisted etching (MAE) process. For example, it may be performed by exposing the silicon-containing layer 20 with metal network 10b to an etching solution, such as a solution containing hydrofluoric acid (HF) and an oxidizing agent, such as H₂O₂. Alternatives to H₂O₂ include Fe(NO₃)₃, and other alternatives indicated for piranha solution above. The duration of the etching process determines the length of resulting silicon nanowires. In general, the etching time may be 1 second and 10 hours. In a more specific embodiment, it will be between 1 minute and 60 minutes. The etching process may be performed at a temperatures of 100° C. or less. For example, it may be performed at room temperature.

After etching, the metal remains around the bottom of the nanowires. Depending on the application, an optional etching step may be applied to remove the metal. In some embodiments, the metal may be removed by wet etching. In some embodiments, if the metal is Au, the etchant may be Aqua Regia which is a mixture of HCl and HNO₃ with a ratio around 1:3. In some embodiments, if the metal is Au, the etchant may be a solution of KI and I₂ with various ratios. It may also be any other gold etchant.

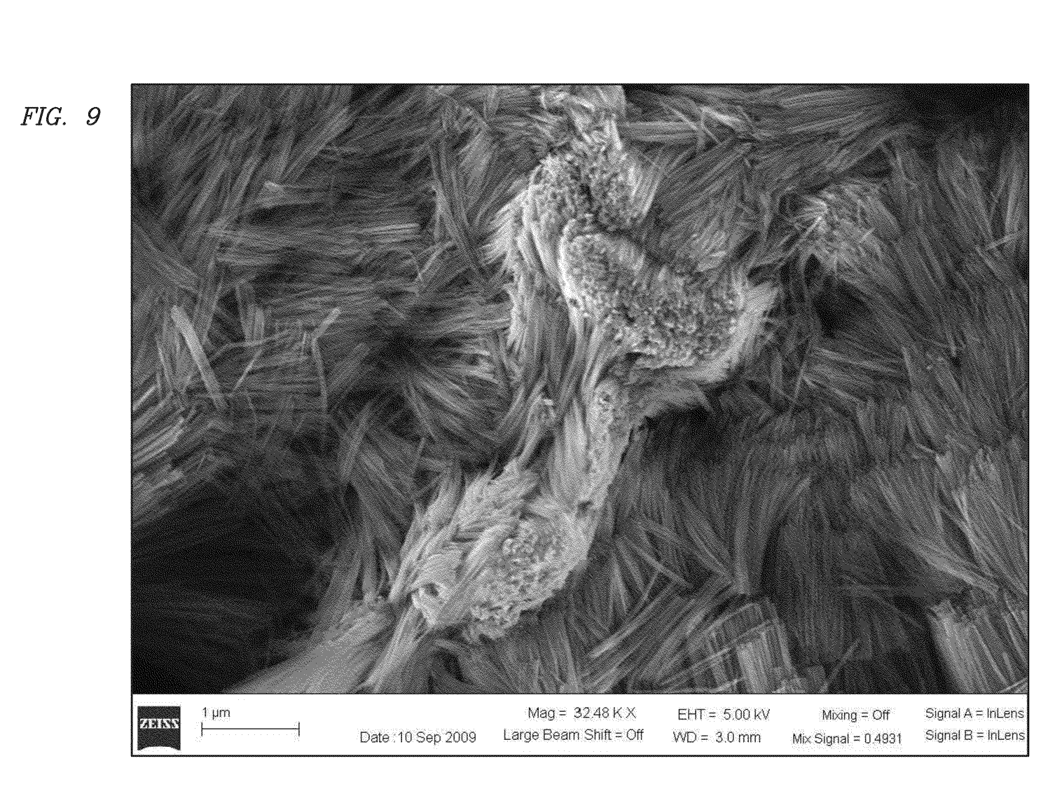

Silicon nanowires 40 resulting from this process may be anchored to the silicon base. Alternatively, if the silicon base is attached to a metal or other conductor prior to etching, the silicon nanowires may be attached to the conductor. The silicon base, which may be in the form of a film, may also be attached to an insulator or another semiconductor prior to etching. Then the silicon nanowires may be attached to the insulator (for example, the silicon nitride shown in FIG. 9) or another semiconductor.

Silicon nanowires 40 may have a width of 100 nm or less, 90 nm or less, 50 nm or less, 30 nm or less, or even 15 nm or less. In some embodiments, silicon nanowires 40 resulting from a single process on a single piece of silicon-containing layer 20 may have a variation in width among wires of 5 nm or less. They may also have a variation in length among wires of 1 nm or less.

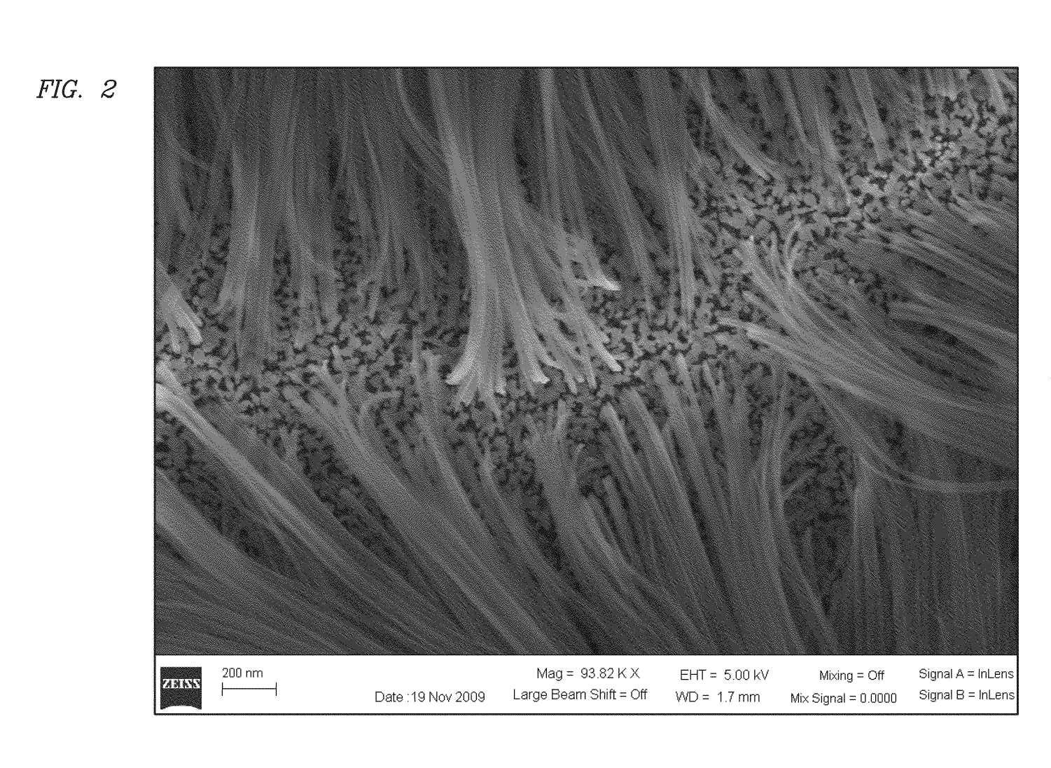

As shown in FIG. 2, the process described above may result in silicon nanowires with a width of 18 nm with a variation of less than 5 nm among wires and a substantially uniform length as detected by a scanning electron microscope (SEM).

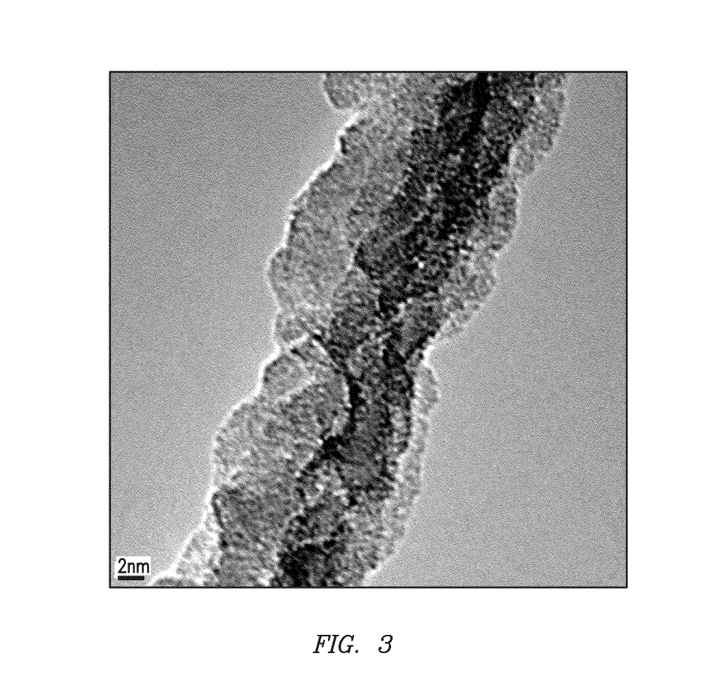

As shown in FIG. 3, the process described above may result in silicon nanowires with a width of 15 nm as detected by a transmission electron microscope (TEM).

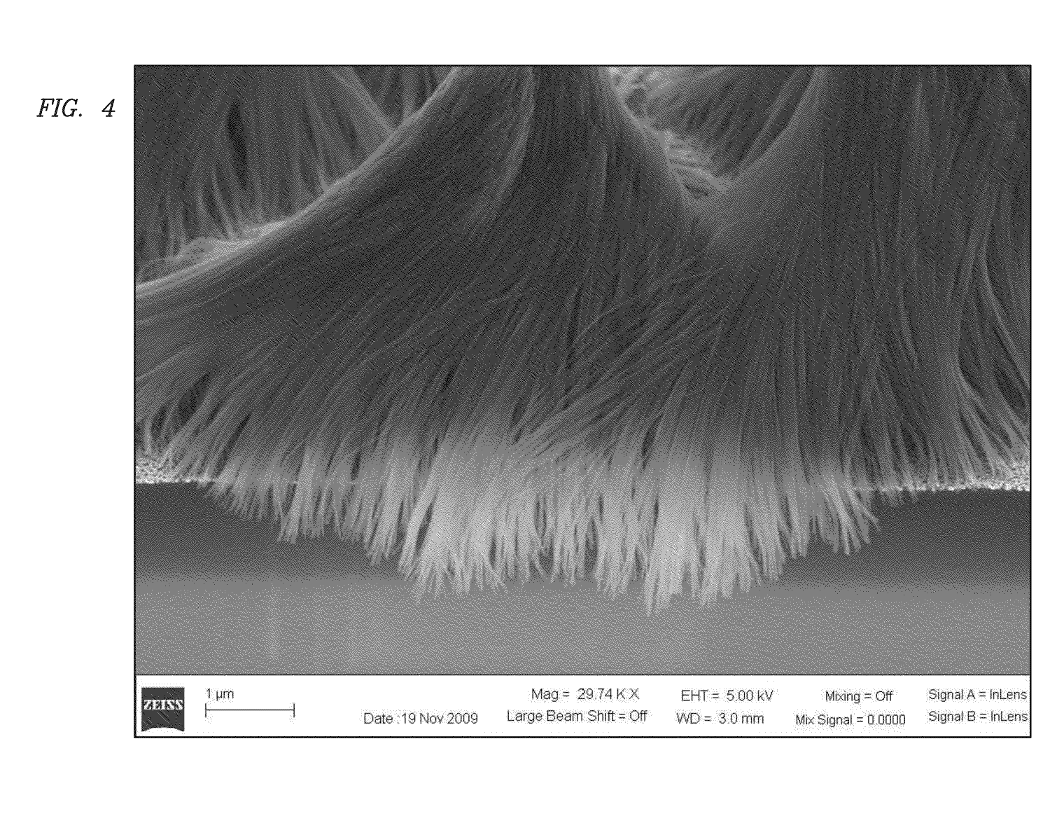

Silicon nanowires produced by processes of the present disclosure may be ultra-dense while they remain attached to the underlying silicon (or, if a conductor is present, the underlying conductor). For example, as shown in FIG. 4, the nanowires density may be as high as 10¹¹ silicon nanowires/cm². In other embodiments, the density may be 10⁸ silicon nanowires/cm².

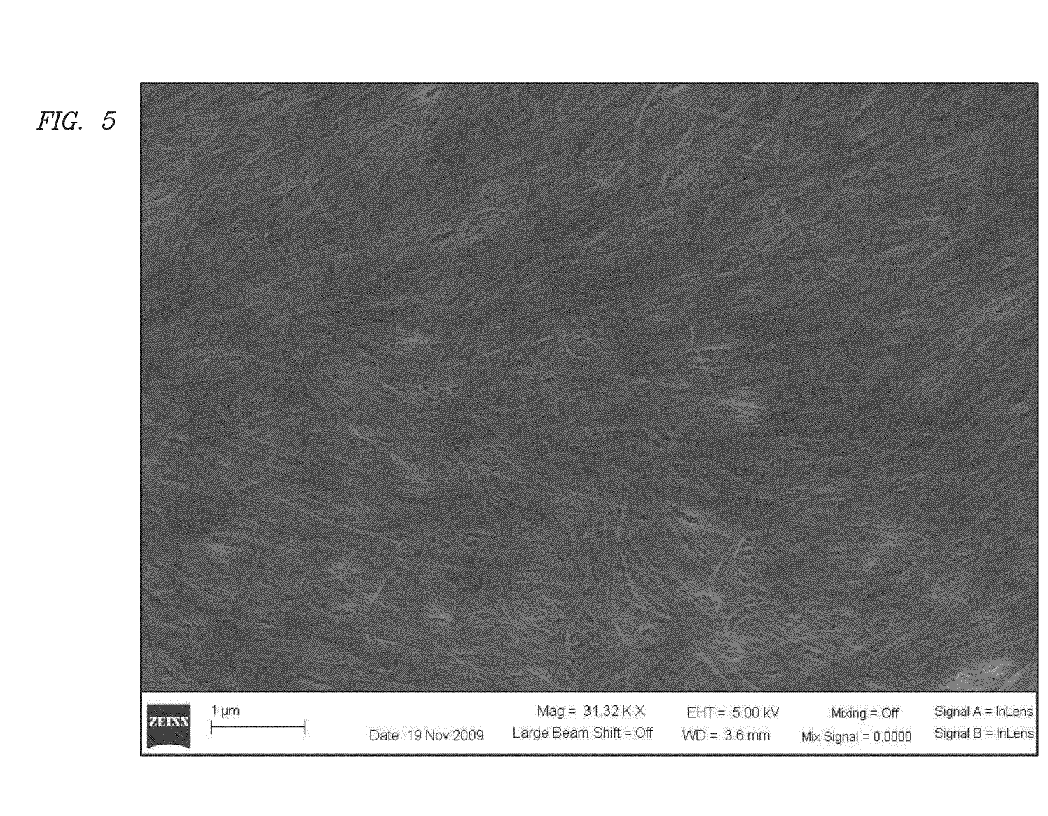

In some embodiments, when the silicon nanowires are sufficiently long and thin, they may collapse into a coat on the silicon (or underlying conductor, insulator or semiconductor, if present) surface, as shown in FIG. 5.

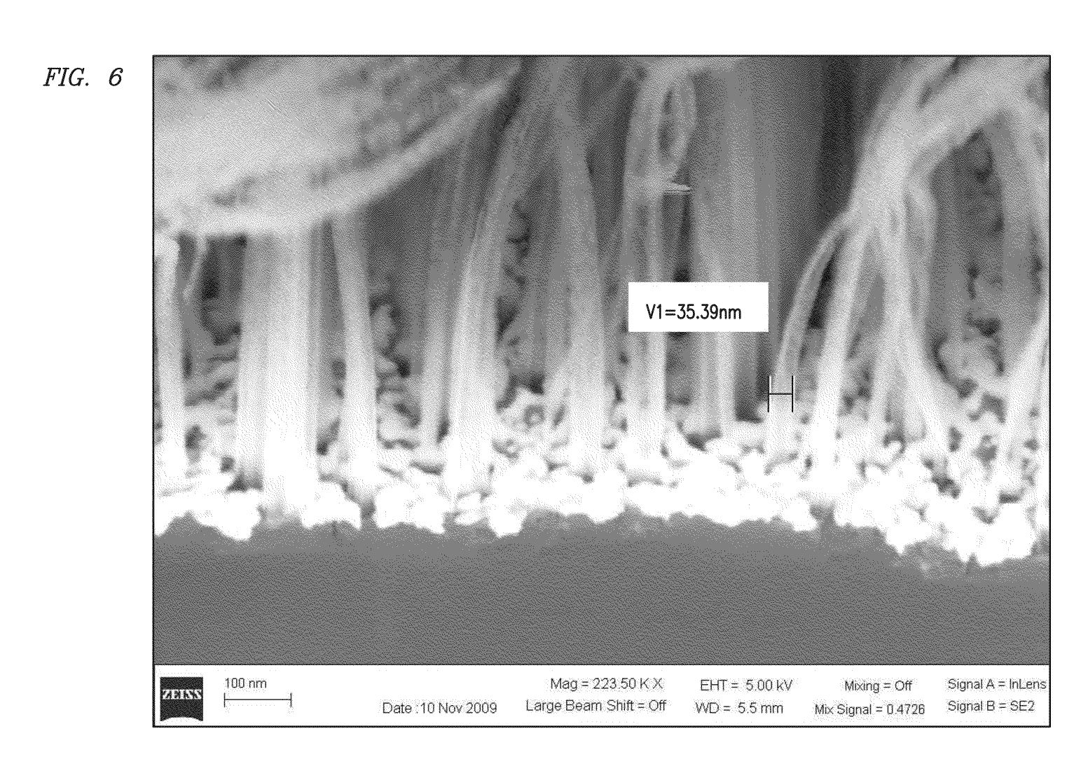

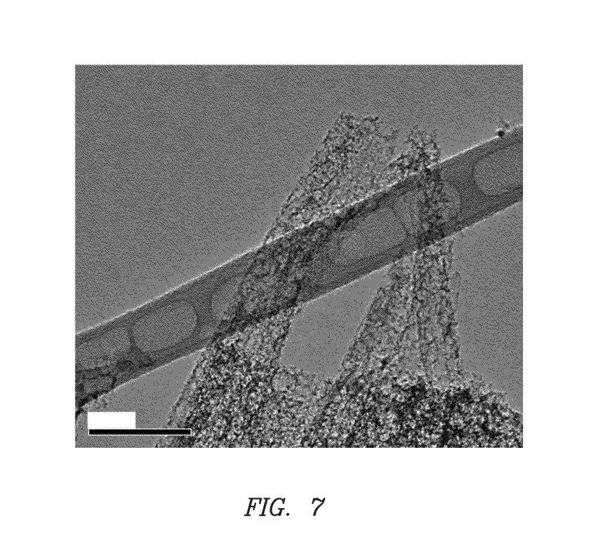

According to another embodiment, porous silicon nanowires may be formed using the above methods. However, silicon-containing layer 20 may be doped with a material known as dopant. For example, silicon-containing layer 20 may be doped with n-type dopants such as P, As, Sb, or p-type dopants such as B, Ga, In. The amount of dopant, along with the etching time, may determine the porosity of the resulting porous silicon nanowires. In specific embodiments, between 5% to 70% of the silicon nanowire volume, on average, may be occupied by pores. Example porous silicon nanowires are presented in FIG. 6 and FIG. 7.

When forming porous silicon nanowires, the etching process may require more time than non-porous silicon nanowires. For example, when forming porous silicon nanowires, the etching time may be between 1 second and 10 hours. The etching time may depend on dopant concentration, etching solution concentration, etching temperature, and other factors. In general, longer etching times and higher dopant concentrations yield more porous nanowires.

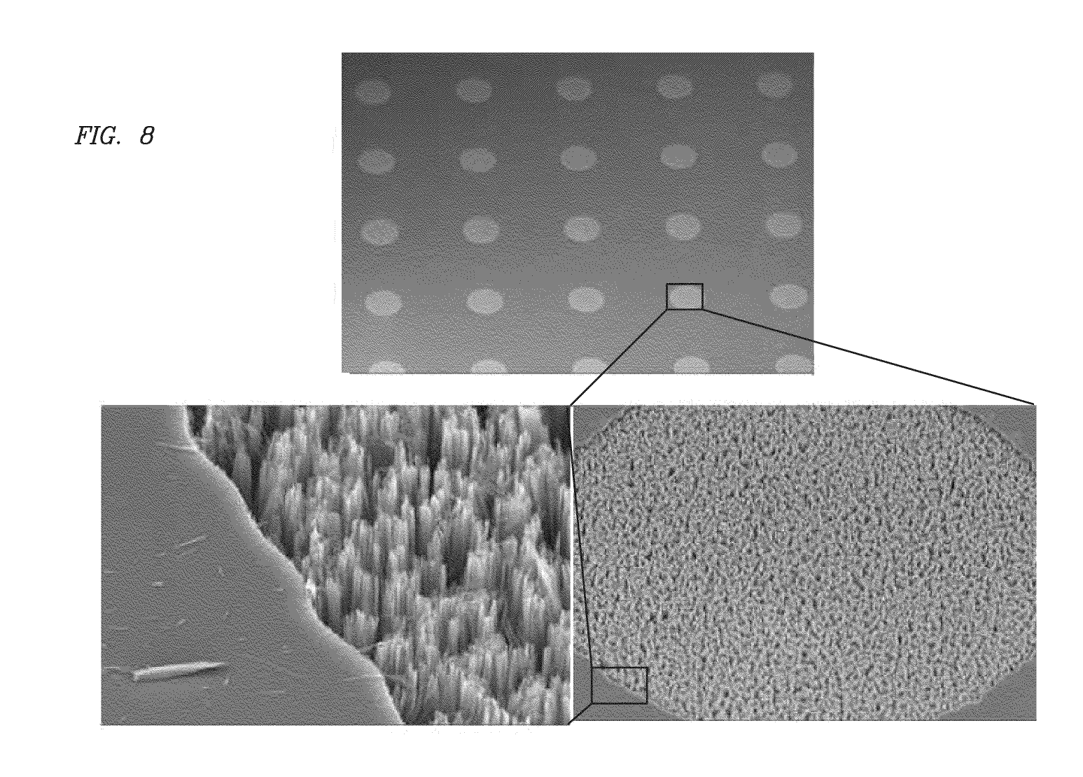

Silicon nanowires may also be formed on the silicon-containing layer 20 (or underlying conductor, insulator or semiconductor, if present) in patterns by first patterning the deposited metal film 10a. Example patterned nanowires are shown in FIG. 8.

In order to form interconnected silicon nanowires, which may be less likely to collapse, a thin metal film 10a may be applied to the silicon-containing layer 20. For example the metal film may be 4 nm thick or less.

In still another embodiment, silicon nanowires may be formed on another film by placing the silicon-containing layer 20 on the film, such as silicon nitride (SiNₓ). The silicon nanowires will have a length generally equal to the thickness of the silicon-containing layer 20. For example, in FIG. 9 the silicon-containing layer was 1.4 μm thick and the resulting silicon nanowires were 1.4 μm long. If the silicon-containing layer does not adhere well with the underlying film, such as SiNₓ, the silicon nanowires after formation may leave the film and become free silicon nanowires, as shown in FIG. 9.

In yet another embodiment, silicon nanowires may be removed from the silicon-containing layer and placed on a metal or other conductor film by transferring the silicon nanowires or by breaking them off the layer, then attaching them to the conductor. In one embodiment, the silicon nanowires may be formed on a sacrificial layer, such as silicon nitride. In another embodiment, sonication may be used to free silicon nanowires.

In another embodiment, fragmented silicon nanowires, which may be in the form of nanowires shorter than those originally formed, or silicon nanoparticles having a length comparable to their width may be formed by subjecting silicon nanowires to sonication, typically to a degree greater than that required simply to remove silicon nanowires from the silicon-containing layer. These fragmented nanowires may also be porous.

In one embodiment, a silicon nanowire containing electrode may be formed by attaching silicon nanowires to a conductive film using a binder. The binder may also contain conductors, such as carbon particles, tin particles.

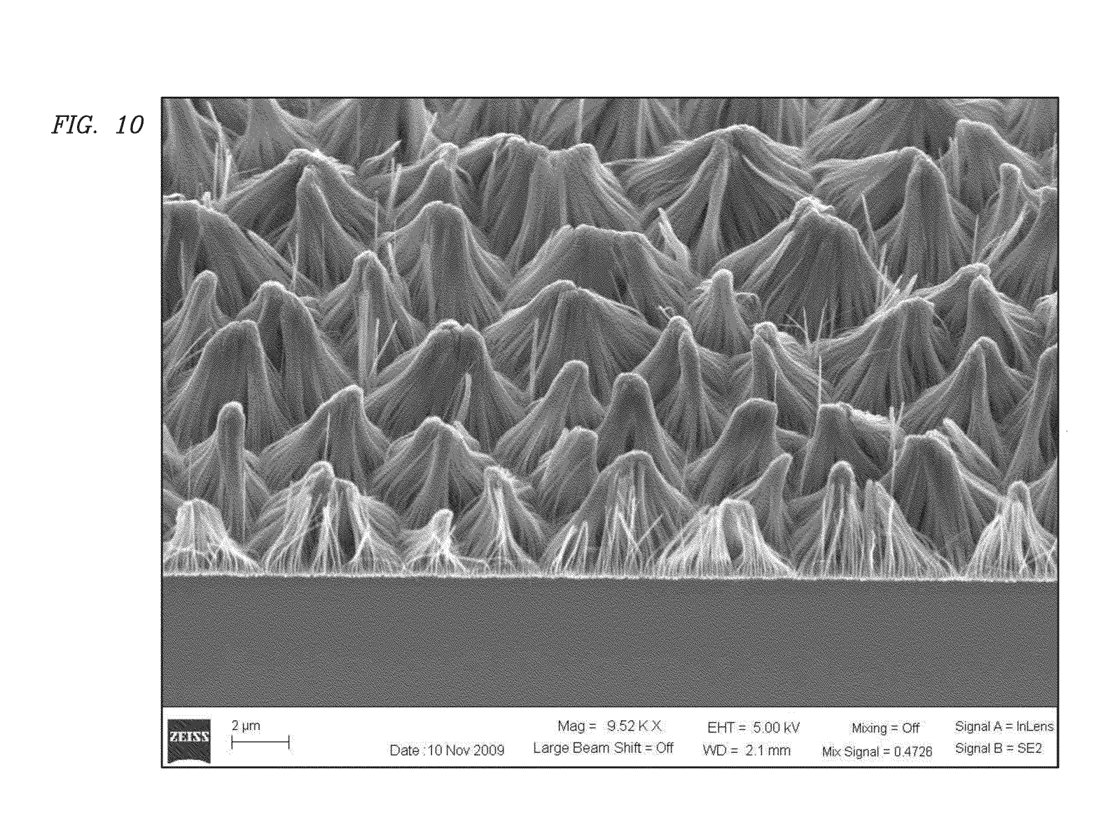

Silicon nanowires may tend to form bunches, as shown in FIG. 10, after wetting. Long, thin silicon nanowires may be particularly prone to bunching. Although bunched silicon nanowires may be useful in some applications, in other applications it may be desirable to avoid them. Nanowire bunching may be decreased or avoided by using critical point drying to avoid surface tension when drying the nanowires. It may also be decreased or avoided by using a liquid with low surface tension for a final nanowire cleaning step. For example, ethyl alcohol has a lower surface tension (22.3 dynes/cm) than water (72.8 dynes/cm) at 20° C. and therefore might make a suitable final cleaning agent. Nanowire bunching may also be decreased or avoided by applying electricity to the silicon nanowires, which will then acquire a charge and repel one another.

### Use of Silicon Nanowires in Lithium-Ion Batteries

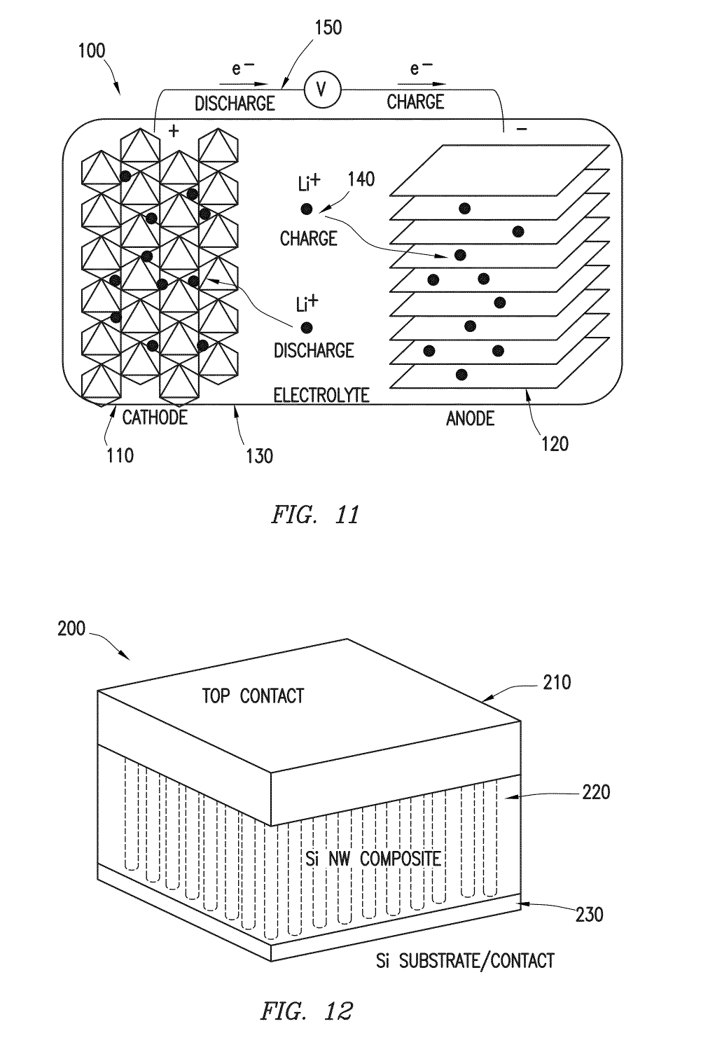

FIG. 11 illustrates the components of a lithium ion battery 100. The battery contains cathode 110, anode 120, and electrolyte 130. During charge and discharge, lithium ions (Li⁺) 140 move between cathode 110 and anode 120 through electrolyte 130 while electrons more through external circuit 150 in the form of an electric current. A separator (not shown) between cathode 110 and anode 120 allows lithium ions 140 to pass, but is electrically insulative, such that electrons must flow through external circuit 150. The example lithium ion battery 100 illustration presented in FIG. 11 is from Teki, R., M. K. Datta, et al., “Nanostructured Silicon Anodes for Lithium Ion Rechargeable Batteries.” Small 5(20): 2236-2242 (2009), incorporated in material part by reference herein.

Cathode 110 may include any cathode material suitable for use in a lithium ion battery. For example, it may include a lithium metal oxide (LiMO₂), such as lithium cobalt oxide (LiCoO₂), or a lithium metal phosphate (LiMPO₄), such as lithium iron phosphate (LiFePO₄). Cathode 110 may contain non electrochemically active materials, such as binders and conductors, in addition to electrochemically active materials.

Electrolyte 130 may be any electrolyte containing lithium ions and suitable for use with the cathode and anode combination. For example it may include a lithium salt in an organic solvent. In specific embodiments, it may include a non-coordinating anion salt, such as lithium hexafluorophosphate (LiPF₆), lithium hexafluoroarsenate monohydrate (LiAsF₆), lithium perchlorate (LiClO₄), lithium tetrafluoroborate (LiBF₄), and lithium triflate (LiCF₃SO₃). Suitable organic solvents include organic carbonates, such as ethylene carbonate or diethyl carbonate.

Anode 120 may contain silicon nanowires formed as described above. Although silicon is a promising anode material for lithium ion batteries due to its theoretical capacity of 4200 mAh/g, as compared to the 372 mAh/g capacity of current graphite anodes. Its potential has not been realized due to a tendency of silicon to crack due to volume changes as lithium ions enter and leave the anode. This cracking impeded the performance of and may ultimately destroy the anode, thereby limiting the number of recharge cycles for the battery. Silicon nanowires may avoid or significantly decrease this cracking problem, greatly improving the number of possible recharge cycles and overall battery life. In one embodiments, silicon nanowires may avoid cracking due to the presence of free space between the nanowires and their ability to move. Porous nanowires may provide even greater strain relaxation capacity.

In addition to avoiding cracking problems, the ability of silicon nanowires to be produced in very dense configurations may allow improvements in power or energy per unit area in lithium ion batteries as compared to those using traditional silicon anode materials. Porous nanowires may also provide improved power density. The pores in the porous silicon nanowires provide more free space and may further reduce the pulverization (e.g. cracking) of a silicon anode.

In particular embodiments, silicon nanowires may be placed in electrical contact with a conductive metal film, such as copper foil, or other conductive film in anode 120. Any silicon-containing layer from which the nanowires are formed may interfere with electrical contact. This interference may be avoided in at least three ways. First, the silicon nanowires may be formed from a silicon-containing layer that is on a metal film prior to etching. Second, the silicon nanowires may be etched from a silicon-containing layer, then transferred to a metal film, for example with the remaining silicon-containing layer intact. In a third process, the silicon nanowires may be formed from a silicon-containing layer, then removed from the layer, for example by being broken off using sonication or other methods. The free silicon nanowires may then be mixed with other anode materials for form a composite anode material on the conductive film. Fragmented silicon nanowires or nanoparticles may be used to form a composite anode material in a similar way.

Silicon nanowires with a width of 20 nm or less may improve battery cycling performance.

### Use of Silicon Nanowires in Thermoelectric Devices

Thermolelectric devices have wide applications in energy harvesting and electrical cooling. Improved thermoelectric devices may greatly reduce energy loss in these processes. For example, 90% of the world's power is generated through heat generation. 60-70% of this heat is lost to the environment. Theremoelectic devices have the ability to recapture some of this wasted heat, thereby reducing energy loss. Conventional thermoelectric devices, however, are too expensive to be put to this use. Silicon nanowires made according to the above processes, however, are relatively cheap. Furthermore, due to increased surface scattering when compared to silicon wafers, even conventional silicon nanowires have a figure of merit (ZT) 100 times higher. Additional improvements in figure of merit may be achieved using nanowires produced according to the above processes because such wires may be thinner than conventional silicon nanowires and because they may be porous, both properties serving to further increase surface scattering.

Thus silicon nanowires may be placed in areas of heat loss in power generators and connected to electrical supplies to supply additional power. Silicon nanowires may also be used in other thermoelectric applications.

An example thermoelectric device containing silicon nanowires is illustrated in FIG. 12. The thermoelectric device 200 may contain top contact 210, silicon nanowires 220, and silicon layer/contact 220. The example thermoelectric device illustration presented in FIG. 12 is from Curtin, B., E. Fang, et al., “Highly Ordered Vertical Silicon Nanowire Array Composite Thin Films for Thermoelectric Devices.” Journal of Electronic Materials 41(5): 887-894 (2012), incorporated in material part by reference herein.

### Use of Silicon Nanowires in Solar Cells

High cost remains the primary barrier to widespread use of solar cells. Half of the cost of solar cells results from the initial silicon costs because only high quality silicon, able to achieve high energy conversion efficiency, may be used. Inexpensive metallurgical grade silicon contains too many impurities for use in solar cells. However, vertically aligned silicon nanowires may be used in the place of high quality silicon. These nanowires may obtain high energy conversion efficiency even when made from metallurgical grade silicon or other silicon with high impurity levels. Silicon nanowires may further improved solar cell performance by increasing light absorption through increased surface area. The width of silicon nanowires may be adjusted using the methods described herein to obtain optimal solar cell efficiency.

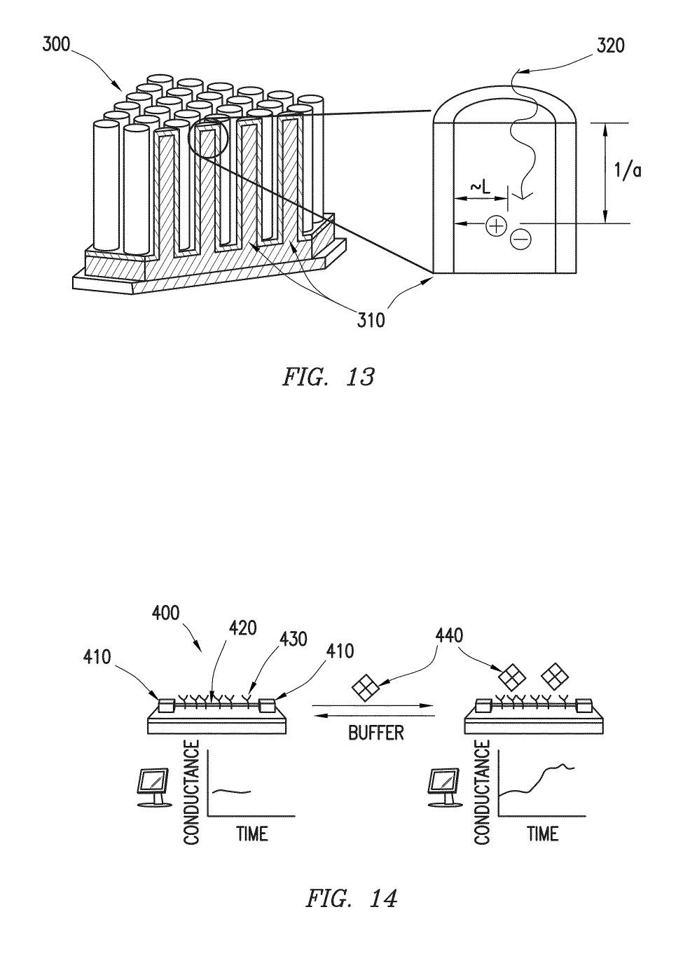

An example solar cell containing silicon nanowires is illustrated in FIG. 13. The solar cell 300 may contain vertically aligned silicon nanowires 310 which receive photons 320. The example solar cell illustration presented in FIG. 13 is from Kayes, B. M., M. A. Filler, et al., “Radial PN junction, wire array solar cells.” Photovoltaic Specialists Conference, 2008. PVSC '08. 33rd IEEE, incorporated in material part by reference herein.

### Use of Silicon Nanowires in Biological and Chemical Sensors

Silicon nanowire field effect transistors (FETs) are emerging as powerful chemical and biological sensors. The abilities of FETs are due largely to the large surface area-to-volume ratio of silicon nanowires as well as their comparability in size to chemical and biological molecules. FETs may provide ultra high sensitivity, label-free detection, and direct electrical real time readouts. The width of silicon nanowires may be adjusted using the methods described herein to optimize sensitivity for different chemical and biological molecules. Furthermore, ultra-thin silicon nanowires may be able to sense some molecules at low concentrations that are no detectable using silicon nanowires fabricated using conventional methods. Furthermore, doped silicon nanowires, which are sometimes useful in FETs, are easier to obtain using the present methods as compared to conventional methods, such as chemical vapor deposition methods.

An example biological sensor containing silicon nanowires is shown in FIG. 14. The biological sensor 400 contains two sets of electrodes 410 electrically contacting with a set of nanowires 420 with receptors 430 attached to the nanowires 420. When target biological molecules 440 bind to receptors 430, conductance between the sets of electrodes 410 through nanowires 420 is changed. The example biological sensor illustration presented in FIG. 14 is from Patolsky, F., G. Zheng, et al., “Nanowire sensors for medicine and the life sciences.” Nanomedicine 1(1): 51-65 (2006).

### Use of Silicon Nanowires in Drug Delivery Devices

Silicon nanowires and particularly porous silicon nanowires prepared according to the methods of this disclosure may be used to deliver drugs within a patient. The drugs may be attached to or located within the pores of the silicon nanowires. In some embodiments, the silicon nanowires may be detached from the silicon-containing layer prior to drug delivery. Silicon nanowires provide enhanced abilities to deliver drugs locally and even into cells. This may improve drug efficacy, lower drug toxicity, or both. In some embodiments, each long silicon nanowire may be fragmented into nanowires with shorter lengths. In some embodiments, the fragmented nanowires may be nanoparticles. The porous or non-porous fragmented nanowires, or porous or non-porous nanoparticles may be used as drug carriers to improve drug efficacy, lower drug toxicity, or both. Silicon nanowires may be used as nanocarriers as generally described in Peer, D. et al., “Nanocarriers as an emerging platform for cancer therapy,” Nature Nanotechnology 2: 751-760 (2007), incorporated in material part by reference herein.

### EXAMPLES

The following examples provide further details regarding certain aspects of the disclosure and are not intended to describe the complete invention.

### Example 1

### Effects of Treatment Time on Nanowire Width

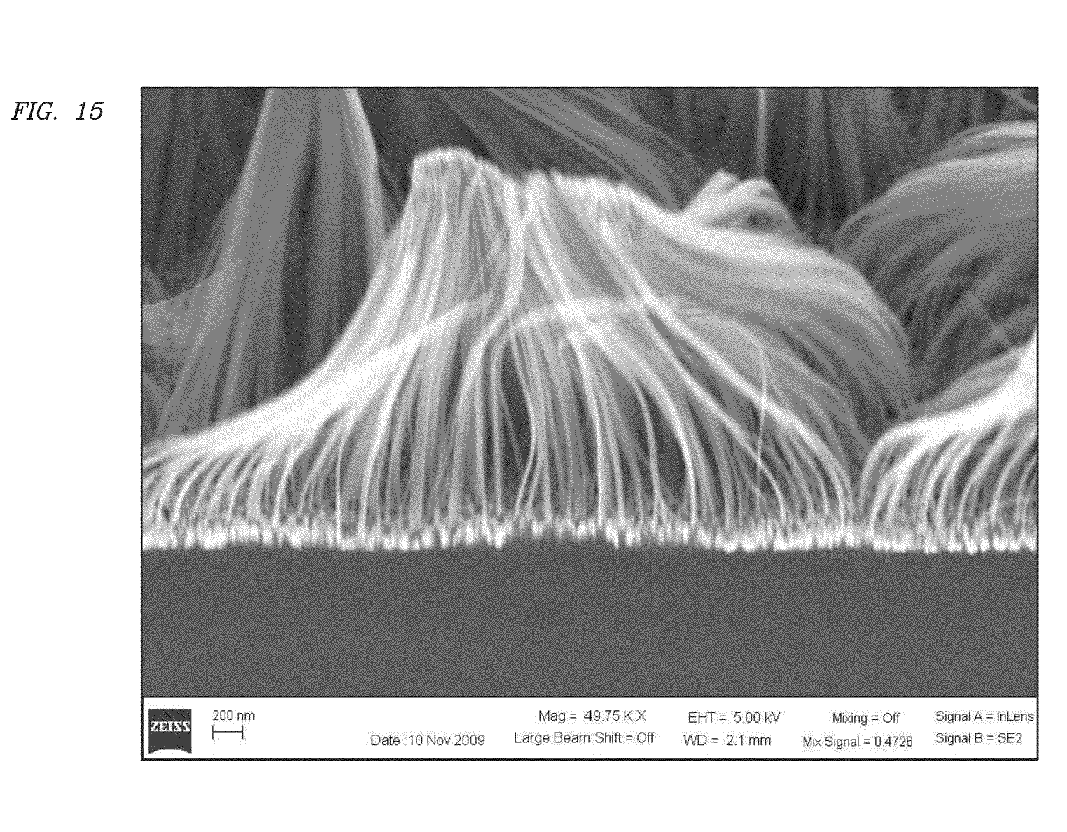

A 25 nm gold film was deposited on silicon and treated for 3 minutes with Piranha solution and the resulting metal network and silicon were etched in a metal-assisted etching process. The resulting nanowires, as shown in FIG. 15, had a width of 20 nm.

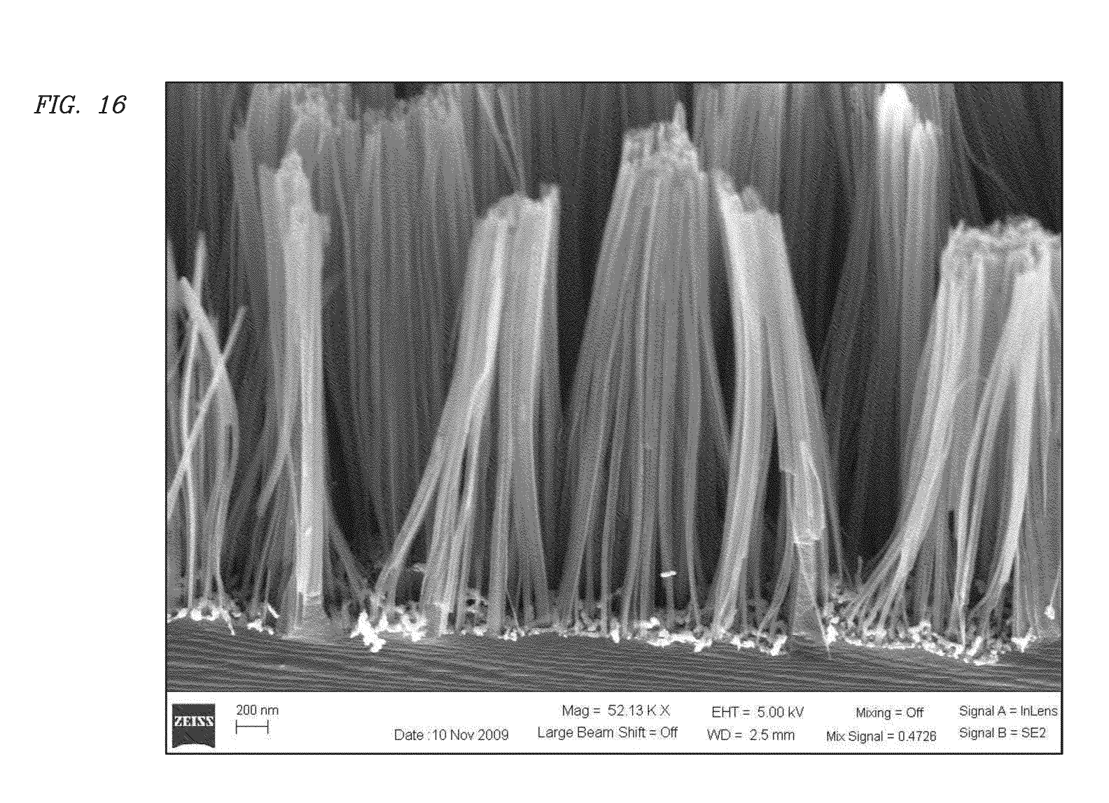

A 25 nm gold film was treated for 15 minutes with Piranha solution and the resulting metal network and silicon were etched in a metal-assisted etching process. The resulting nanowires, as shown in FIG. 16, had a width of 40 nm.

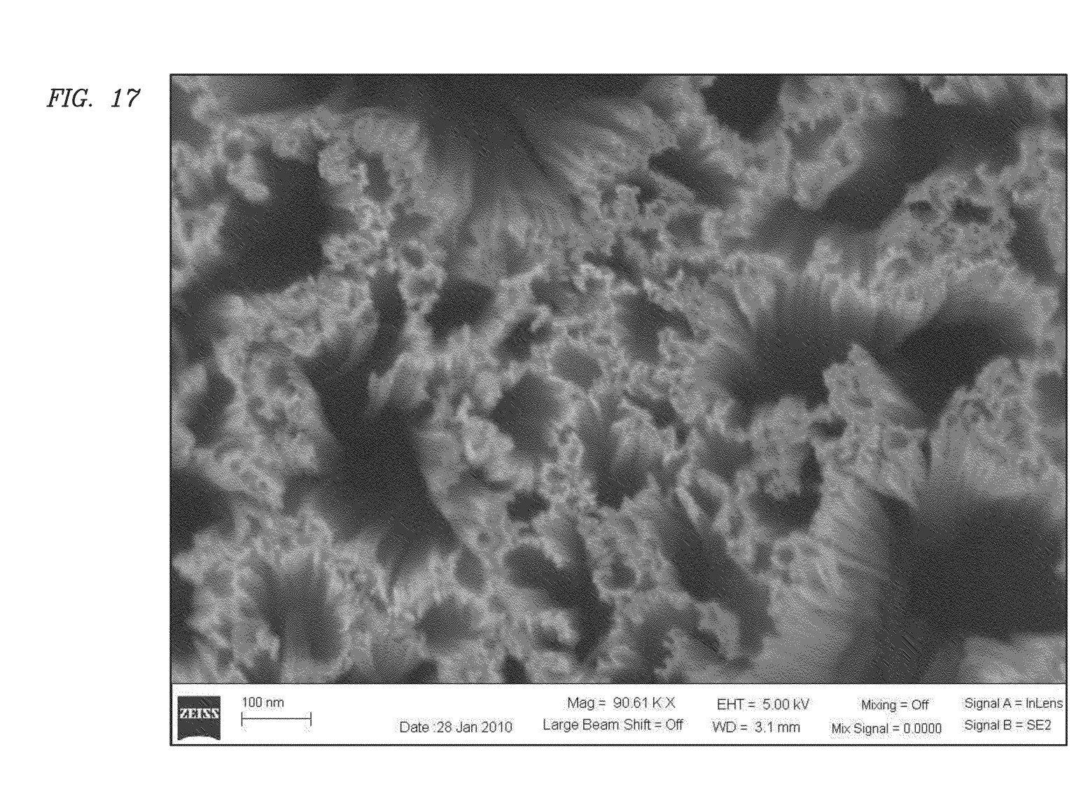

A 3 nm gold film was treated for 3 minutes with Piranha solution and the resulting metal network and silicon were etched in a metal-assisted etching process. The resulting nanowires were interconnected, as shown in FIG. 17.

### Example 2

### Silicon Nanowire Anode for a Lithium Ion Battery

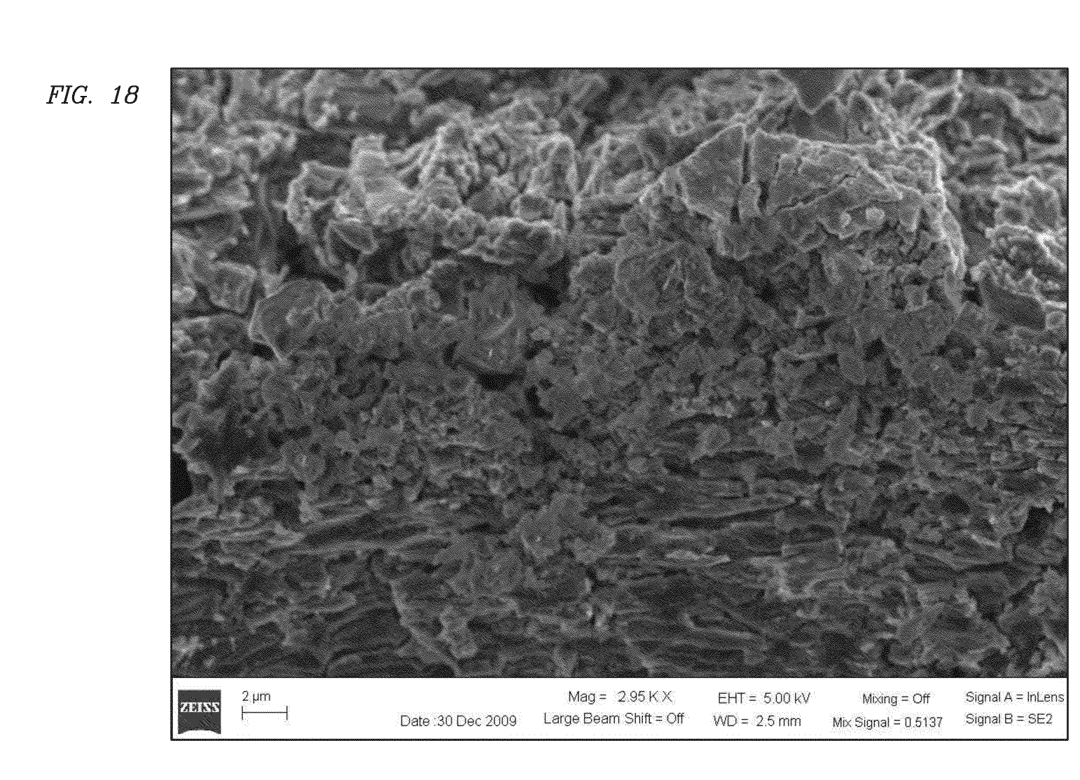

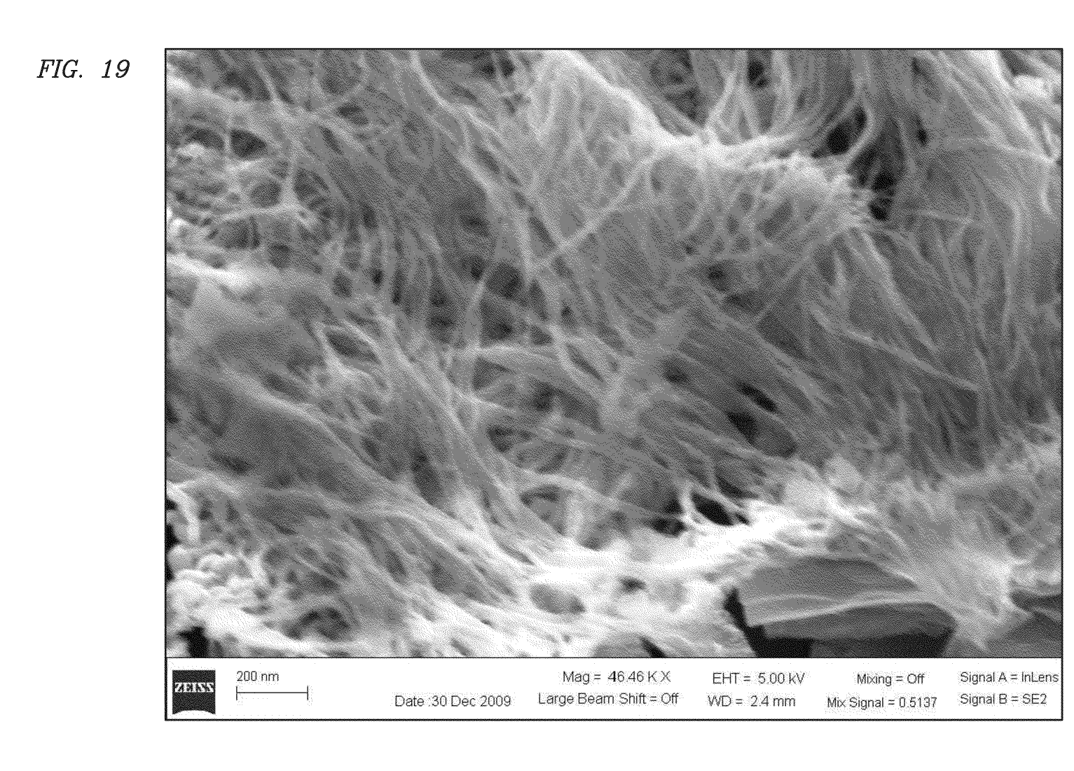

Silicon nanowires with a width of 30 nm or less were fabricated using a highly Sb-doped N-type silicon wafer layer to form a silicon nanowire anode. The resulting nanowires were about 5 μm long. The resistivity of the silicon nanowire anode was 0.008-0.02 ohm-cm. The anode was combined with a lithium cobalt oxide (LiCoO₂) cathode in a test cell and cycled. Although the silicon wafer exhibited substantial cracking after cycling (FIG. 18), the silicon nanowires showed no damage (FIG. 19).

Although only exemplary embodiments of the invention are specifically described above, it will be appreciated that modifications and variations of these examples are possible without departing from the spirit and intended scope of the invention. For instance, numeric values expressed herein will be understood to include minor variations and thus embodiments “about” or “approximately” the expressed numeric value unless context, such as reporting as experimental data, makes clear that the number is intended to be a precise amount.

1. A method of fabricating a silicon nanowire having a width of 100 nm or less comprising:
depositing a metal film on a silicon-containing layer;
treating the metal film using a wet process to produce an interconnected metal network having gaps on the silicon-containing layer;
etching the silicon-containing layer with a metal-assisted etching process to form a silicon nanowire having a width of 100 nm or less by controlling the width of silicon nanowire through controlling the width of the gaps and a length that is controlled by controlling the duration of etching.

2. (canceled)

3. (canceled)

4. The method of claim 1, wherein the silicon nanowire has a width of 50 nm or less.

5. The method of claim 1, wherein the silicon nanowire has a width of 30 nm or less.

6. The method of claim 1, wherein the silicon-containing layer comprises polycrystalline silicon, amorphous silicon, or a single crystalline silicon wafer.

7. The method of claim 1, wherein the silicon-containing layer comprises a dopant, and wherein the etching process forms a porous silicon nanowire

8. The method of claim 1, wherein the silicon-containing layer comprises a metal or other conductor attached to the side opposite the metal film.

9. The method of claim 8, wherein the silicon nanowire is attached to the metal or other conductor.

10. The method of claim 1, wherein the silicon-containing layer comprises an insulator or semiconductor.

11. The method of claim 10, wherein the silicon nanowire is attached to the insulator or semiconductor.

12. The method of claim 1, further comprising detaching the silicon nanowire from the silicon-containing layer.

13. The method of claim 1, wherein the entire method is conducted at a temperature of 150° C. or less.

14. The method of claim 1, wherein the metal is gold.

15. The method of claim 1, wherein the wet process comprises treating the metal film with a solution comprising hydrogen peroxide and sulfuric acid.

16. The method of claim 1, wherein the metal-assisted etching process comprises exposing the silicon-containing layer with the metal network to an etching solution comprising hydrofluoric acid and an oxidizing agent.

17. The method of claim 1, wherein the etching process forms a plurality of silicon nanowires on the silicon-containing layer having a density of up to 10¹¹ silicon nanowires/cm².

18. The method of claim 7, wherein the etching process forms a plurality of silicon nanowires on the metal or conductor having a density of up to 10¹¹ silicon nanowires/cm².

19. The method of claim 1, comprising patterning the deposited metal film in order to obtain a pattern of silicon nanowires after the etching process.

20. The method of claim 1, comprising depositing a metal film 4 nm thick or less and forming interconnected metal nanowires.

21. The method of claim 1, further comprising fragmenting the silicon nanowire to form fragmented silicon nanowires or silicon nanoparticles.

22. The method of claim 21, wherein fragmenting comprises sonication.

23. (canceled)

24. (canceled)

25. (canceled)

26. (canceled)

27. (canceled)

28. (canceled)

29. (canceled)

30. (canceled)
